(19) United States
(12) Patent Application Publication
(10) Pub. No.: US 2003/0062559 A1
(43) Pub. Date: Apr. 3, 2003

(54) Semiconductor device

(76) Inventor: Satoshi Tamaki, Tokyo (JP)

Correspondence Address: Darryl G. Walker, WALKER & SAKO, LLP, Suite 235, 300 South First Street, San Jose, CA, 95113, US

(21) Appl. No.: 10/287,238

(22) Filed: Nov. 4, 2002

Related U.S. Application Data
(63) Continuation of application No. 09/495,128, filed on Feb. 1, 2000.

(30) Foreign Application Priority Data
Feb. 2, 1999 (JP) 25561/1999

(51) Int. Cl. H01L 27/108

(52) U.S. Cl. 257/296

(57) ABSTRACT

A semiconductor device is disclosed that may reduce adverse effects, such as a dynamic random access memory (DRAM) readout operation failure, which may result from substrate noise generated outside a DRAM portion (macro). Noise may be generated by a logic circuit, as but one example. According to one embodiment an application specific integrated circuit (ASIC) can include a built-in DRAM macro (002) and a large-scale logic circuit unit (007), or the like. The entire DRAM macro (002), which can include an internal power supply circuit (004) and a DRAM cell array unit (006), may be formed in a well, such as a deep n-well (005). Power may be supplied to the DRAM macro (002) by the internal power supply circuit (004). Voltage fluctuations in a substrate due to substrate noise generated from the logic circuit unit (007) can be received by a DRAM memory cell unit (063) and the internal power supply circuit (004) to the same degree. This can reduce malfunctions such as the holding of improper data values that can arise from the above-described noise.

This application is a continuation of U.S. patent application Ser. No. 09/495,128 filed on Feb. 1, 2000.

### TECHNICAL FIELD

The present invention relates generally to semiconductor devices and more particularly to semiconductor devices that include a dynamic random access memory (DRAM) integrated with another unit that can generate substrate noise which adversely effects the operation of the DRAM.

### BACKGROUND OF THE INVENTION

Some integrated circuits can integrate a memory device with some other circuit unit. In particular, an application specific integrated circuit (ASIC) or a microcomputer chip can include a large sized DRAM portion (a DRAM “macro”) as well as a logic unit. Conventionally, input terminals for a power supply and for a ground (GND) are provided separately for the DRAM macro and the logic unit. Further, the wiring provided for a power supply and a ground supply are made thicker. Thicker wiring can reduce the adverse effects of power supply noise generated from outside the DRAM macro.

FIG. 8 shows one example of a conventional ASIC chip that includes a DRAM macro.

As shown in FIG. 8, an ASIC chip 001 can include a DRAM macro 002 and a logic circuit unit 007. A DRAM macro 002 has a DRAM control circuit 003 and an internal power supply circuit 004. The DRAM control circuit 003 can include a DRAM cell array unit 006.

A power supply (VDD) 201 and ground (GND) 202 can be supplied to the DRAM macro 002 through pads Pa and Pb, respectively. The internal power supply circuit 004 can provide voltages, shown as 401, 402, 403 and 404 that are different than a power supply (VDD) and a ground (GND).

A power supply (VDD) 101 and ground (GND) 102 can also be supplied to the logic circuit unit 007 through pads Pc and Pd, respectively. Power supply (VDD) 101 and ground (GND) 102 are different connections than power supply (VDD) 201 and ground (GND) 202.

In the conventional example of FIG. 8, the ASIC chip 001 includes a deep n-well 005. Only the DRAM cell array unit 006 is formed in the deep n-well 005.

As shown in FIG. 8, data input/output (I/O) signal lines 302 can be connected between the DRAM control circuit 003 and logic circuit unit 007. Further, in the particular arrangement of FIG. 8, a logic circuit unit 007 may further be connected to the DRAM controller circuit 003 by control and address signals 301.

As also shown in FIG. 8, the logic circuit unit 007 may receive and transmit signals by way of I/O signal line group terminal 701.

FIG. 9 shows a DRAM control circuit 003 in detail. As shown in FIG. 9, the DRAM control circuit 003 is mainly composed of a DRAM cell array unit 006, a timing generator 031, an X-decoder unit 032, a Y-decoder unit 033, and a read/write buffer 034.

The timing generator 031, the X-decoder unit 032, and the Y-decoder unit 033 can receive control and address signal lines 301 as inputs. The read/write buffer 034 can be connected to data input/output signal lines 302.

The DRAM cell array unit 006 can include a Word line 061, a bit line 062, and a DRAM cell unit 063. A sense amplifier unit (such as 066) can read data from and write data to a DRAM cell unit (such as 063).

The DRAM control circuit 003 may be connected to various power supply lines. In particular, a power supply (VDD) line 201 may be supplied to the timing generator 031, the Y-decoder unit 033, and the read/write buffer 034. A word line 061 may receive a VBOOT power supply from the X-decoder unit 032, which can be connected to the VBOOT power supply line 402. The VBOOT power supply may be generated from an internal power supply circuit (such as 004). An internal power supply circuit (such as 004) may also supply a VINT power supply to a bit line 062 and a sense amplifier 066 on VINT power supply line 401.

FIG. 9 further shows lines for carrying a VBB voltage 404 and a half power supply HVINT 403. These voltages will be described in more detail with reference to FIG. 10.

FIG. 10 shows a DRAM cell unit 063. A DRAM cell unit 063 may include a memory cell transistor 065 and a cell capacitor 064. The “back” gate of memory cell transistor 065 can be connected to a negative voltage VBB supply line 404. A negative voltage VBB supply can be provided by an internal power supply circuit (such as 004). A cell capacitor 064 can have one terminal connected to the half power supply HVINT line 403. The half power supply HVINT may be equivalent to ½VINT, and provided by an internal power supply circuit (such as 004).

FIG. 10 also shows a word line 061 and a bit line 062. As shown, a word line 061 may be connected to a memory cell transistor 065 gate. A bit line 062 may be connected to a memory cell transistor 065 source/drain.

FIG. 11 represents a side cross sectional view of a DRAM cell unit 063 and a sense amplifier unit 066 formed in a chip substrate. FIG. 11 also shows, in an equivalent way, power supply circuits connected to various contacts. An internal power supply circuit 004 and a DRAM control circuit 003 are shown to be connected to a power supply VDD line 201 and to a ground supply GND line 202.

As shown in FIG. 11, a ground GND supply line 202 may be connected to a sense amplifier unit 066 by an equivalent resistance 037. An internal power supply VINT line 401 may be connected to a sense amplifier unit 066 by an equivalent resistance 035. A VBOOT power supply line 402 may be connected to a word line 061 by an equivalent resistance 036.

The cross sectional view of FIG. 11 also shows a deep n-well 005 formed in a substrate. A p-well 051 may be formed in the deep n-well 005. N-channel transistors may be formed within the p-well 051. P-well 051 may further include an n-well 052. P-channel transistors may be formed in n-well 052.

Deep n-well 005 may be connected to power supply VDD line 201 by a parasitic resistance 053 (which includes a contact C). N-well 052 may be connected to power supply VDD line 201 by a parasitic resistance (not shown). P-well 051 may be connected to negative voltage VBB line 404 through a parasitic resistance 054 (which includes a contact B).

As also shown in FIG. 11, a logic circuit unit 007 may be coupled to deep n-well 005 by a substrate route 710, which can include parasitic resistance 071. A contact D is included in the representation of the substrate route 710. A parasitic capacitance 055 may exist between contact D and contact C. A parasitic capacitance 056 may exist between contact C and contact B. A parasitic capacitance 057 may exist between contact B and a contact A. Contact A can represent the connection between cell capacitor 064 and a diffusion region in p-well 051.

FIG. 12 shows an equivalent circuit to the arrangement of FIG. 11. FIG. 12 includes many of the same constituents as FIG. 11. To that extent, like constituents will be referred to by the same reference character. FIG. 12 also includes equivalent resistance 058 that may connect the half supply voltage HVINT line 403 to a cell capacitor 064. The connection is shown as contact E.

Referring now to FIGS. 11 and 12, noise (for example, a voltage fluctuation in the substrate) can be generated from logic circuit unit 007. Such noise may be coupled to a DRAM cell unit 063 by way of parasitic resistance 071 and parasitic capacitance 055, 056, and 057.

Generally parasitic resistance 053 and 054, that may result from deep n-well 005 and p-well 051, can have a high value. Substrate resistance 071 may have a low value.

Resistance 035, 036, and 058, connected to internal power supply VINT line 401, VBOOT power supply line 402, and half power supply HVINT line 403, respectively, can be wiring resistance. Wiring resistance 035, 036, and 058 can be set to a low value, relative to resistance 053 and 054. Such a low value can be a countermeasure to power supply noise generated in a DRAM macro. In particular, wiring resistance 035, 036, and 058 can be designed to reduce the influence of variations in the potential on the various supply lines 401, 402 and 403.

If reference is made back to FIG. 8, it is shown that the DRAM macro 002 and logic circuit unit 007 include separate terminals for receiving a power supply VDD 201/101 and ground GND 202/102. Such an arrangement can serve as a countermeasure against noise in the logic circuit unit 007 affecting the operation of the DRAM macro 002.

However, such an arrangement may not address the problem of substrate noise discussed above, with reference to FIGS. 11 and 12.

One example of the adverse effects of logic circuit unit 007 substrate noise affecting the operation of a DRAM macro 002 is shown in FIG. 13. FIG. 13 includes a waveform WORD LINE that can represent the response of a word line (such as 061), a waveform BIT LINE that can represent the response of a bit line (such as 062), a waveform CONTACT E that can represent the response of contact E shown in FIGS. 11 and 12, a waveform CONTACT A that can represent the response of contact A shown in FIGS. 11 and 12, and a waveform LOGIC CIRCUIT that can represent noise generated by a logic circuit unit 007.

As shown in FIG. 13, while the WORD LINE, BIT LINE, and CONTACT E can be essentially not affected by substrate noise, the substrate noise of the LOGIC CIRCUIT UNIT can affect the response of CONTACT A. In particular, the potential of the CONTACT A waveform may rise above a threshold level (“LOW THRESHOLD”) for sensing a low logic value. Consequently, while a memory cell may store a logic low value, such a logic low value may be erroneously read or refreshed as a logic high value.

Japanese Patent Laid-Open Application (Kokai) No. 5-267617 discloses a DRAM that includes a well for the exclusive use of memory cells. The memory cell well is electrically separated from a well formed for peripheral circuits and may receive a zero bias voltage by way of a resistance element.

Despite the electrically separate wells, the embodiments of Kokai No. 5-267617 have essentially the same structure as the conventional example described in FIGS. 8-13. Thus, the embodiments of Kokai No. 5-267617 do not address the above-described drawbacks discussed in conjunction with the conventional example of FIGS. 8-13.

As will be described at a later point herein, the present invention can improve the data holding operation of a DRAM cell by forming an internal power supply circuit and DRAM cell units within the same deep n-well. In such an arrangement, noise received from outside the deep n-well can affect both the internal power supply circuit and the DRAM cell units to the same degree. In this way, adverse noise effects can be reduced.

The embodiments of Kokai No. 5-267617 can be considered to have essentially the same structure as the conventional case described in FIGS. 8-13, because only the DRAM cell units are formed in the n-well, which can be a deep n-well. The technique presented in the aforementioned publication is said to address noise generated in peripheral circuits by forming only DRAM cell units within a deep n-well. However, the present invention addresses drawbacks present when DRAM cells units are formed in a deep n-well. As described above, there can be noise that effects essentially only the DRAM cell units. Further, such noise can be at high levels. Therefore, the technique presented in Kokai No. 5-267617 does not address the drawbacks present in conventional approaches as described above.

Also, the present invention can form a parasitic capacitance between memory cell plate and a p-well. Such a parasitic capacitance is shown as Cpw in Kokai No. 5-267617. However, with the present invention, unlike the above-reference, the adverse effects of noise generated outside a deep n-well, such as that due to parasitic capacitance shown as Cws in the reference, can be reduced.

It is further noted that the first embodiment described in Kokai No. 5-267617 describes the harmful influences of the parasitic capacitance Cws (the junction capacitance between substrate 1 and p-type well 23). In particular, the reference discusses adverse effects that result from making the p-well for the DRAM cell units at a ground GND potential. However, since the present invention describes embodiments in which a memory cell unit p-well is placed at a negative potential, the present invention may not include the harmful effects associated with a p-well at a ground potential.

As will be described in more detail at a later point herein, the present invention can include an internal power supply circuit that is formed in a deep n-well. Such an arrangement can make it possible to restrain large fluctuations in an internal power supply, due to noise such as that described in Kokai No. 5-267617. In the example of Kokai No. 5-267617, the harmful influences of parasitic capacitance Cws and Cpw discussed in the conjunction with the first embodiment of the reference can be addressed by the present invention. Further, the approach specified in Kokai No. 5-267617 differs from that of the present invention in that it uses a resistance 25 and the like to address the harmful effects of such capacitance.

The present invention can address the drawbacks that exist in the current art discussed above. One goal of the present invention to provide a semiconductor device that can reduce such harmful effects as readout failures of a DRAM cell due to substrate noise from outside a DRAM macro. Such noise may be generated by an integrated logic circuit, as but one example.

### SUMMARY OF THE INVENTION

A semiconductor device according to one embodiment of the present invention may comprise dynamic random access memory (DRAM) circuit formed in a well. A DRAM circuit may include DRAM cells and a power supply unit is formed in the same well as the DRAM cells. Such a power supply unit can provide one or more supply voltages to various portions of the DRAM circuit.

According to one aspect of the embodiments, a semiconductor device may further comprise a logic circuit unit formed on the same substrate as the above-mentioned DRAM units.

According to another aspect of the embodiments, a semiconductor device may further comprise compensation capacitance for a power supply unit formed in the same well as a DRAM circuit. Compensation capacitance may be formed between wiring that supplies one or more internal supply voltages, and the well.

According to another aspect of the embodiments, a DRAM circuit can include a word line, a bit line, a cell capacitor, and/or a cell transistor connected to various internal supply wirings. Compensation capacitance is provided such that when substrate potential fluctuations occur, the potential of the word line, bit line, cell capacitor, and/or cell transistor correspondingly fluctuate.

According to another aspect of the embodiments, a DRAM circuit may include compensation capacitance for a word line supply, a bit line supply, a cell capacitor supply and a cell transistor supply, as noted above. In addition, the DRAM circuit may include a first compensation capacitance provided in a power supply unit. The first compensation capacitance may be formed between a first power supply wiring (a power supply wiring other than those mentioned above) and a well containing the power supply unit and DRAM cells. In such an arrangement, the potential of the first power supply wiring can fluctuate in response to substrate fluctuations.

According to another aspect of the embodiments, a DRAM circuit may include compensation capacitance for a word line supply, a bit line supply, a cell capacitor supply and a cell transistor supply as noted above. In addition, the DRAM circuit may include a second compensation capacitance provided in a power supply unit. The second compensation capacitance may be formed between a ground supply wiring and a well containing the power supply unit and DRAM cells. In such an arrangement, the potential of the ground supply wiring will fluctuate in response to substrate fluctuations.

According to another aspect of the embodiments, a semiconductor device may include a power supply unit that includes a first insulated gate field effect transistor (IGFET) provided between a supply input voltage wiring (that may receive an external power supply voltage) and a power supply wiring for a DRAM portion of the semiconductor device. The gate of the first IGFET can be grounded.

According to another aspect of the embodiments, a semiconductor device may include a power supply unit that includes a second IGFET provided between a ground input voltage wiring (that may receive an external ground supply voltage) and a ground supply wiring for a DRAM portion of the semiconductor device. The gate of the first IGFET can be connected to a supply input voltage wiring that receives an external power supply voltage.

According to another aspect of the embodiments, a semiconductor device may include first and second IGFETs as described above. Further, the first and second IGFETs may be of complementary conductivity types.

According to another aspect of the embodiments, a semiconductor device of the present invention may include an application specific integrated circuit (ASIC) that includes a built-in DRAM (“macro”) and a large-scale logic circuit, or the like. The DRAM macro can include a DRAM control unit with a DRAM cell array unit and an internal power supply circuit formed in a well, such as a “deep” n-well. Power can be supplied to the DRAM macro by the internal power supply circuit. In such an arrangement, voltage fluctuations in the substrate, due to substrate noise generated by the logic circuit, can be received by the internal power supply circuit and the DRAM control unit at essentially the same degree. Such an arrangement can prevent malfunctions, such as the holding of improper data values resulting from such noise.

According to another aspect of the embodiments, a semiconductor device can include DRAM cells and an internal power supply circuit formed in a well. The internal power supply circuit can include one or more internal power supply lines. At least one compensation capacitor can be connected to the internal power supply lines. One terminal of the compensation capacitor can be connected to the well. Thus, substrate noise generated by a logic circuit, or the like, can result in fluctuations in the internal power supply lines.

According to another aspect of the embodiments, a semiconductor device may include a DRAM macro with a power supply unit. The power supply unit can include a p-channel IGFET between a supply input voltage wiring (that may receive an external power supply voltage) and a power supply wiring for the DRAM macro. The gate of the p-channel IGFET can be grounded. A compensation capacitance can be provided between the power supply wiring and a well that includes the-DRAM macro. In this arrangement, due to the compensation capacitance, noise generated in the substrate can result in corresponding fluctuations in the power supply wiring.

According to another aspect of the embodiments, a semiconductor device may include a DRAM macro with a power supply unit. The power supply unit can include an n-channel IGFET between a ground input voltage wiring (that may receive an external ground supply voltage) and a ground supply wiring for the DRAM macro. The gate of the n-channel IGFET can be connected to a supply input voltage wiring. A compensation capacitance can be provided between the ground supply wiring and a well that includes the DRAM macro. In this arrangement, due to the compensation capacitance, noise generated in the substrate can result in corresponding fluctuations in the ground supply wiring.

### BRIEF DESCRIPTION OF THE DRAWINGS

FIG. 1 is a circuit block diagram of a first embodiment of a semiconductor device according to the present invention.

FIG. 2 is a circuit block diagram showing the structure of a DRAM macro that may be used in the first embodiment of the present invention.

FIG. 3 is a representation of a side cross sectional view showing a DRAM cell unit and sense amplifier unit formed in a chip substrate according to a first embodiment.

FIG. 4 is an equivalent circuit diagram of the arrangement of FIG. 3.

FIG. 5 is a timing diagram showing the response of one embodiment to substrate noise.

FIG. 6 is a circuit block diagram showing the structure of an internal power supply circuit according to one embodiment.

FIG. 7 is a circuit block diagram showing the structure of an internal power supply circuit according to another embodiment.

FIG. 8 is a circuit block diagram of a conventional semiconductor device.

FIG. 9 is a circuit block diagram showing the structure of a conventional DRAM macro.

FIG. 10 is a circuit diagram of a conventional DRAM cell unit.

FIG. 11 is a representation of a side cross sectional view showing a DRAM cell unit and sense amplifier unit formed in a chip substrate according to a conventional semiconductor device.

FIG. 12 is an equivalent circuit diagram of the arrangement of FIG. 11.

FIG. 13 is a timing diagram showing the response of a conventional semiconductor device to substrate noise.

### DETAILED DESCRIPTION OF THE EMBODIMENTS

Various embodiments of a semiconductor device according to the present invention will now be described with reference to a number of figures.

Components that may be equivalent to those described in the conventional example will be referred to by the same reference character. Further, a detailed description of such components will not be repeated.

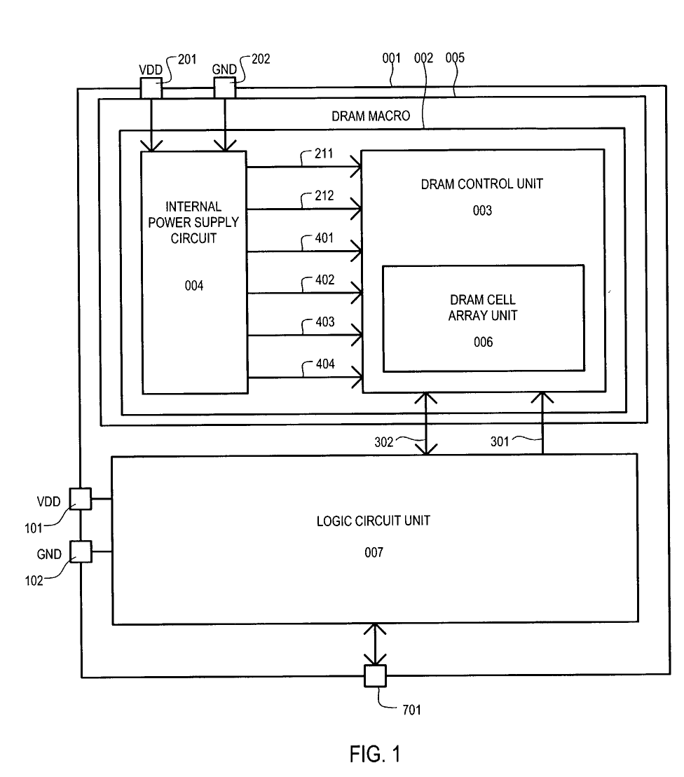

Referring now to FIGS. 1-6, a first embodiment will now be described. First, the general structure of the first embodiment will be described.

Referring now to FIG. 1, an application specific integrated circuit (ASIC) 001 is shown that includes a logic circuit unit 007 and a DRAM macro 002. The DRAM macro 002 may be formed in a deep n-well 005.

The logic circuit unit 007 may be connected to an I/O signal line group terminal 701. The logic circuit unit 007 may receive power from a power supply VDD terminal 101 and ground supply GND terminal 102.

The DRAM macro 002 may receive address and control signal lines 301 from the logic circuit unit 007. Further, data I/O signal lines 302 may be coupled between the logic circuit unit 007 and the DRAM macro 002. The DRAM macro 002 may receive power through a power supply VDD terminal 201 and a ground supply GND terminal 202. In particular embodiments, the power supply VDD terminal 201 and ground supply GND terminal 202 may be exclusively used for the internal power supply circuit 004.

A DRAM macro 002 may include an internal power supply circuit 004 and a DRAM control circuit 003. A DRAM control circuit 003 includes a DRAM cell array unit 006. A number of power supply lines 401, 402, 403 and 404 can be connected between the internal power supply circuit 004 and DRAM control circuit 003. The internal power supply circuit 004 may provide various power supply voltages to DRAM control circuit 003 on power supply lines 401, 402, 403 and 404.

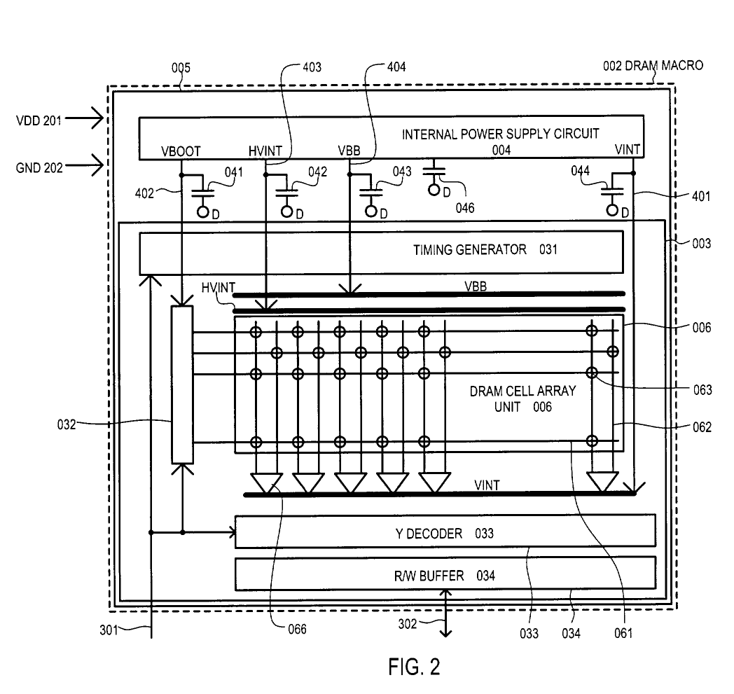

FIG. 2 shows a more detailed representation of a DRAM macro, such as that shown as 002 in FIG. 1.

In the particular arrangement of FIG. 2, the entire DRAM macro 002 may be formed within a deep n-well 005. The DRAM macro 002 may include an internal power supply circuit 004 and a DRAM control circuit 003. The DRAM control circuit 003 may include a DRAM cell array unit 006.

As shown in FIG. 2, internal power supply circuit 004 provides power supply voltages on power supply lines 401, 402, 403 and 404 to various portions of the DRAM control circuit 003. In addition, a number of compensation capacitances 041, 042, 043 and 044 are provided between the internal power supply lines and a deep n-well 005. More particularly, compensation capacitances 041, 042, 043 and 044 are provided between power supply lines 402, 403, 404 and 401, respectively and deep n-well 005.

A DRAM control circuit 003 may include a timing generator 031, a DRAM cell array unit 006, an X-decoder unit 032, a Y-decoder unit 03,3, and a read/write buffer 034. In addition, a DRAM control circuit 003 may include a word line 061, a bit line 062, a DRAM cell unit 063 and a sense amplifier unit 066.

A power supply voltage VDD can be supplied to the Y-decoder unit 033 and the read/write buffer 034 by way of a power supply voltage VDD terminal 201. A word line 061 may receive a VBOOT power supply voltage from VBOOT power supply line 402, by way of X-decoder unit 032. A bit line 062 and sense amplifier unit 066 may receive a VINT power supply voltage from VINT power supply line 401.

A semiconductor device according to the present invention may include a DRAM cell unit such as that shown in FIG. 10. Thus, a negative voltage VBB may be provided to the back gate of a DRAM cell unit from negative voltage VBB power supply line 404. A half supply voltage HVINT may be provided to a memory cell capacitor plate from half supply voltage HVINT line 403.

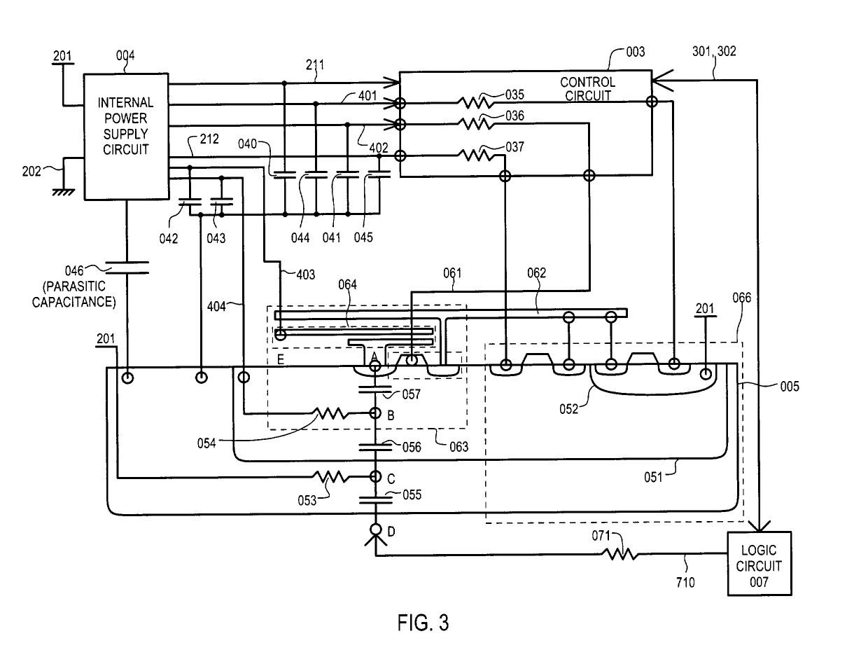

FIG. 3 represents a side cross sectional view of a DRAM cell unit 063 and a sense amplifier unit 066 formed in a chip substrate. FIG. 3 also shows, in an equivalent way, power supply circuits connected to various contacts. Internal power supply circuit 004 can be connected to a power supply VDD line 201 and to a ground GND supply line 202.

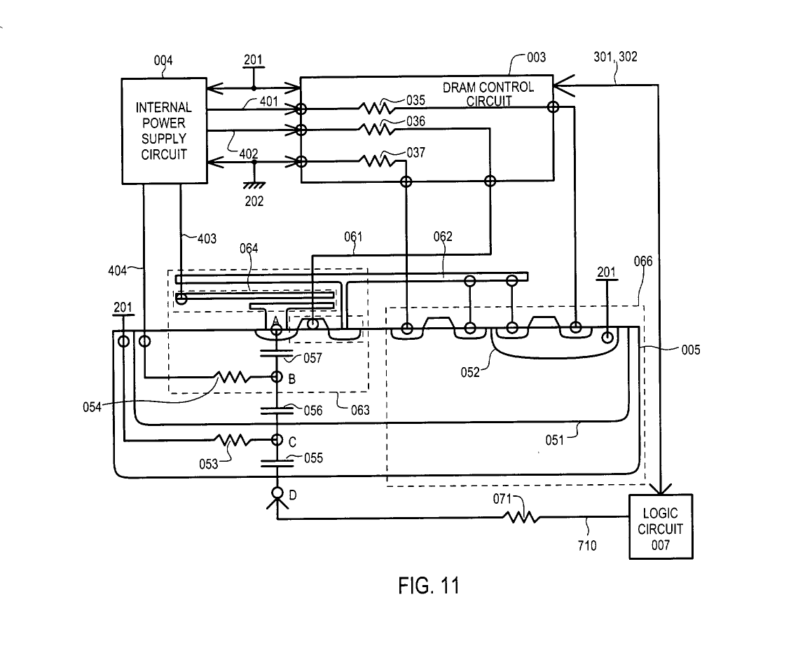

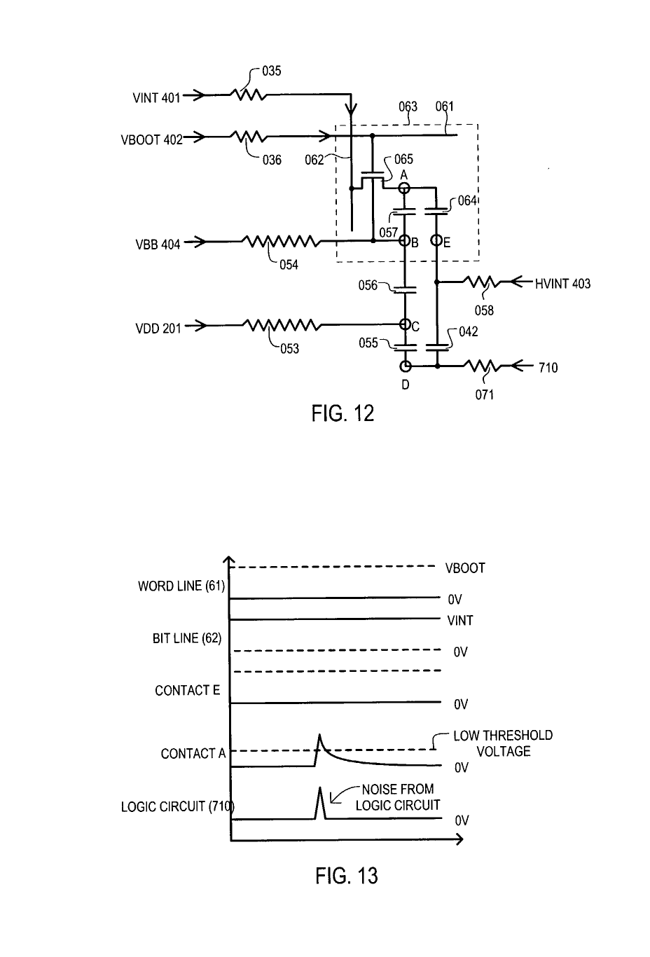

In the arrangement of FIG. 11, an internal ground GND supply line 212 may be connected to a sense amplifier unit 066 by an equivalent resistance 037. An internal power supply VINT line 401 may be connected to a sense amplifier unit 066 by an equivalent resistance 035. A VBOOT power supply line 402 may be connected to a word line 061 by an equivalent resistance 036.

In the embodiment of FIG. 3, the internal power supply circuit 004 may be located within deep n-well 005. The internal power supply 004 can be conceptualized as being connected to the deep n-well through a parasitic capacitance 046. Further, internal power supply wiring 401, 402, 403 and 404 can be coupled to compensation capacitance 044, 041, 042 and 043. Compensation capacitance 044, 041, 042 and 043 can have a terminal coupled to the deep n-well 005. Further, internal power supply wiring 211 and internal ground supply wiring 212 can be coupled to deep n-well 005 by compensation capacitance 040 and 045, respectively.

FIG. 3 also shows that a deep n-well 005 may be formed in a substrate. A p-well 051 may be formed in the deep n-well 005. N-channel transistors may be formed within the p-well 051. P-well 051 may further include an n-well 052. P-channel transistors may be formed in n-well 052.

Deep n-well 005 may be connected to power supply VDD line 201 by a parasitic resistance 053 (which includes a contact C). N-well 052 may be connected to power supply VDD line 201 by a parasitic resistance (not shown). P-well 051 may be connected to negative voltage VBB 404 through a parasitic resistance 054 (which includes a contact B).

As also shown in FIG. 3, a logic circuit unit 007 may be coupled to deep n-well 005 by a substrate route 710 that includes parasitic resistance 071. A contact D is included in the representation of the substrate route 710. A parasitic capacitance 055 may exist between contact D and contact C. A parasitic capacitance 056 may exist between contact C and contact B. A parasitic capacitance 057 may exist between contact B and a contact A. Contact A can represent the connection between cell capacitor 064 and a diffusion region within p-well 051.

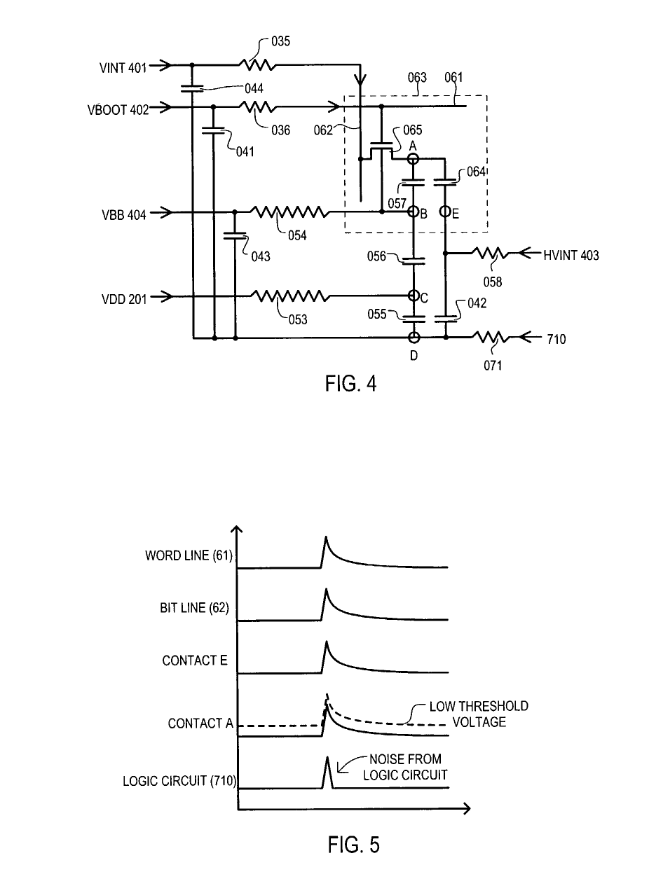

FIG. 4 shows an equivalent circuit to the arrangement of FIG. 3. FIG. 4 includes many of the same constituents as FIG. 3. To that extent like constituents will be referred to by the same reference character. FIG. 4 also includes equivalent resistance 058 that may connect the half supply voltage HVINT line 403 to a cell capacitor 064. The connection is shown as contact E.

As shown in FIGS. 4 and 3, there can exist a transmission route for noise (voltage fluctuations in the substrate) generated by a logic circuit unit 007. A transmission route can include parasitic resistance 071 and parasitic capacitance 055, 056 and 057 between contacts A and D.

As also shown in FIGS. 4 and 3, an internal power supply voltage VINT from supply line 401 can be connected to a bit line 062 through an equivalent resistance 035 of a DRAM control circuit 003. A word line 061 can be connected to a VBOOT power supply line 402 through equivalent resistance 036. A negative voltage VBB from supply line 404 can be connected to contact B through a parasitic resistance 054. The VBB supply line 404 may be coupled to a deep n-well 005 by parasitic capacitance 043. A parasitic resistance 054 may be formed by the diffused layer of p-well 051. A power supply VDD line 201 can be connected to the deep n-well 005 through parasitic resistance 053. A parasitic resistance 053 can be formed by the diffused layer of deep n-well 005.

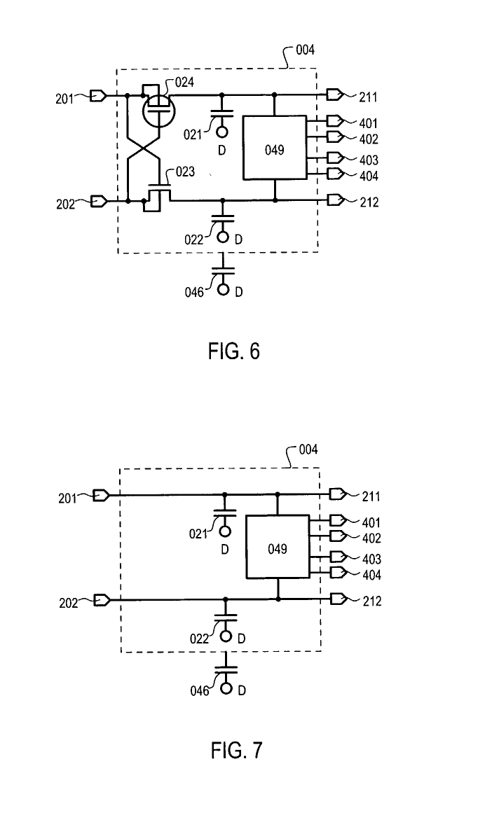

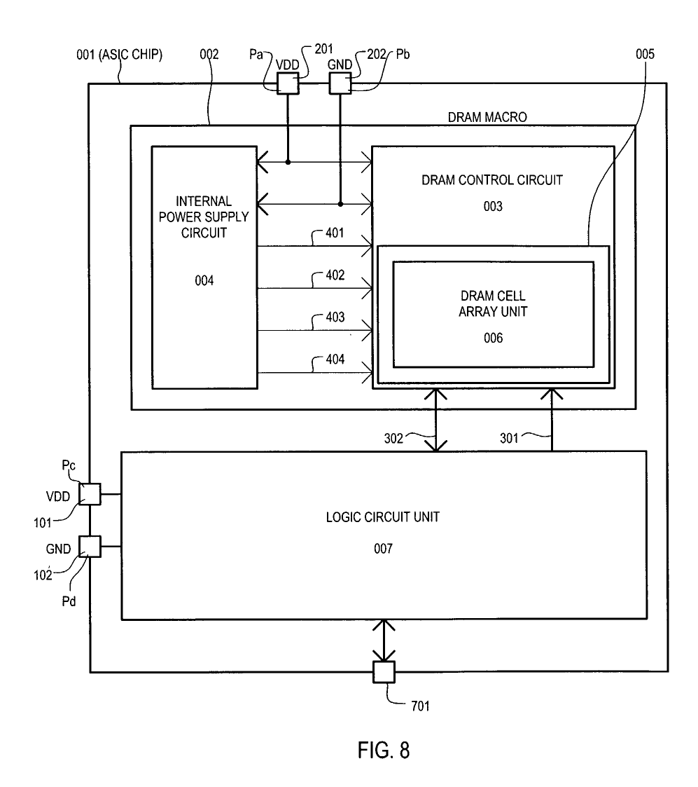

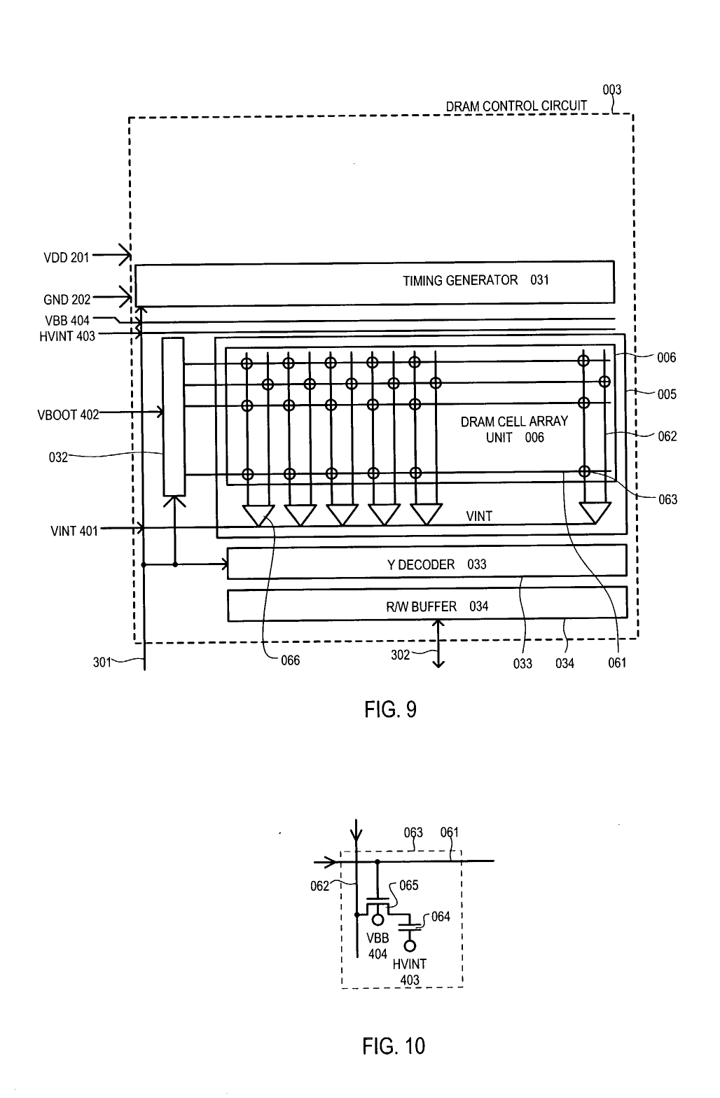

Referring now to FIG. 6, an internal power supply circuit, such as that shown as items 004 in FIGS. 1-3, is shown in more detail.

As shown in FIG. 6, an internal power supply circuit 004 can include a different voltage supply circuit 049. Different voltage supply circuit 049 can receive a power supply voltage VDD from line 201 and a ground voltage GND from line 202. The voltage VDD and ground voltage on lines 201 and 202 can be used exclusively in the DRAM macro 002. Different voltage supply circuit 049 can supply voltages that are different than supply voltage VDD or ground GND. More particularly, a different voltage supply circuit 049 can provide an internal supply voltage VINT, a VBOOT supply voltage, a half supply voltage HVINT, and a negative voltage VBB on lines 401, 402, 403 and 404.

The internal power supply circuit 004 of FIG. 6 may also include an n-channel transistor 023 situated between a ground supply line 202 and internal ground GND supply line 212. The gate of n-channel transistor 023 can be connected to a power supply VDD line 201. N-channel transistor 023 can introduce a resistance between supply lines 202 and 212. As shown in FIG. 6, a power supply circuit 004 may also include a compensation capacitance 022 between internal ground supply wiring 212 and a deep n-well 005 (shown as contact D).

FIG. 6 also shows a p-channel transistor 024 situated between a power supply VDD line 201 and internal power VDD supply line 211. The gate of p-channel transistor 024 can be connected to a ground GND supply line 202. P-channel transistor 024 can introduce a resistance between power supply lines 201 and 211. As shown in FIG. 6, a power supply circuit 004 may further include a compensation capacitance 021 between internal power supply wiring 211 and a deep n-well 005 (shown as contact D).

Next, the operation of a preferred embodiment will be described.

An embodiment of the present invention can include a structure such as that shown in FIG. 1. Further, the embodiment may include compensation capacitance 044, 041, 042 and 043, each having a terminal connected to a deep n-well 005. In such an arrangement, the voltage on internal power supply wirings 401, 402, 403 and 404 may follow voltage fluctuations within deep n-well 005.

If reference is made to the equivalent circuit of FIG. 4, the resistance of parasitic resistances 053 and 054 can be formed by diffused layers. Consequently, such resistances (053 and 054) can be relatively high. In contrast, the equivalent resistances 035, 036 and 058 can be a wiring resistance. Consequently, such resistances (035, 036, and 058) can be relatively low.

In the present invention, an internal power supply circuit 004 may be formed in a deep n-well 005 along with a DRAM cell array unit 006. Thus, as shown in FIGS. 3 and 6, an internal power supply circuit 004 may be connected to a substrate by a parasitic capacitance 046.

In the above-described structure, noise (which can include voltage fluctuations in the substrate) generated from a logic circuit 007, can result in fluctuations at contact D. Due to compensation capacitances 041, 042 and 044, such fluctuations can result in corresponding fluctuations in the voltage on internal power supply lines 402, 403 and 401. Such fluctuations on internal power supply lines (402, 403 and 401) may result in fluctuations at the terminals of a word line 061, a DRAM cell capacitor 064, and a bit line 062.

Reference is made to FIG. 5, which includes five waveforms. A waveform WORD LINE can represent the response of a word line (such as 061), a waveform BIT LINE that can represent the response of a bit line (such as 062), a waveform CONTACT E that can represent the response of contact E shown in FIGS. 3 and 4, a waveform CONTACT A can represent the response of contact A shown in FIGS. 3 and 4, and a waveform LOGIC CIRCUIT that can represent noise generated by a logic circuit unit 007. The waveform CONTACT A can also include a low threshold level (shown as a dashed line).

As shown in FIG. 5, fluctuations due to noise in the substrate can result in corresponding fluctuations at contact A and a low threshold level. This can illustrate how a cell level can be prevented from undesirably rising higher than a bit line level. This can prevent readout failures that can occur in conventional approaches.

The effect of an embodiment of the present invention will now be described.

According to the present invention, potentials of a word line 061, bit line 062 and DRAM cell capacitor 064 can fluctuate in the same general fashion as a substrate, when substrate noise is generated by a logic circuit 007. In this way, fluctuations in a DRAM cell level relative to a bit line level can be restrained. This can prevent the adverse effects of substrate noise on memory cell readout operations that may occur in conventional approaches.

Referring now to FIG. 7, a second embodiment of the present invention will now be described.

In the embodiment of FIG. 7, a power supply VDD wiring 201 and ground supply GND wiring 202 may be directly connected to internal power supply VDD wiring 211 and internal ground supply GND wiring 212, respectively. The arrangement of FIG. 7 does not include intervening transistors, such as those shown as items 023 and 024 in FIG. 6. An arrangement such as that of FIG. 7 may be effective for low substrate noise cases.

According to the present invention, a semiconductor device includes a DRAM cell array unit 006 and an internal power supply circuit 004 formed in the same deep n-well 005. Voltage fluctuations in the substrate, due to a peripheral circuit for example, can affect the DRAM cell array unit 006 and internal power supply circuit 004 to essentially the same degree. Malfunctions, such as those caused by improper data holding, can thereby be reduced, ideally to a minimum degree.

One skilled in the art would recognize that while the description refers to “contacts A, B, C, D and E, such contacts may be representative of a conductive connection are not necessarily integrated contact structures formed by etching a contact hole or the like. Along these same lines, while various supplies are described as being “connected” to circuit structures, such a connection may be by way of an intermediate circuit structure. As but one example, the HVINT supply may be connected by way of precharge circuits to bit lines. Still further, while a supply VDD and ground are described, a supply VDD may be less than or greater than an externally provided supply voltage. Similarly, a “ground” may be a “virtual” ground that is less than or greater than an externally provided ground potential.

It is understood that while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a dynamic random access memory (DRAM) unit formed in a well, the DRAM unit including at least one DRAM cell unit and at least one sense amplifier; and
an internal power supply circuit formed in the well that supplies internal power supply voltages to the DRAM unit.

2. The semiconductor device of claim 1, further including:
a logic circuit unit formed in the same substrate as the DRAM unit.

3. The semiconductor device of claim 1, further including:
internal supply wiring between the internal power supply unit and the DRAM unit; and
compensation capacitance between the internal supply wiring and the well.

4. The semiconductor device of claim 3, wherein:
the DRAM unit further includes at least one bit line, at least one word line, and the DRAM cell unit includes at least one cell transistor and at least one cell capacitor;
the internal supply wiring is coupled to the at least one bit line, at least one word line and at least one memory cell unit; and
the compensation capacitance provides fluctuations in the potentials provided by the internal supply wiring in response to fluctuations in the potential of the substrate.

5. The semiconductor device of claim 3, wherein:
the compensation capacitance includes a parasitic capacitance between the internal supply wiring and the well.

6. The semiconductor device of claim 1, wherein:
the internal power supply circuit includes an internal power supply wiring and power supply compensation capacitance coupled between the internal power supply wiring and the well, the internal power supply wiring providing a fluctuation in a power supply potential on the internal power supply wiring in response to fluctuations in the potential of the substrate.

7. The semiconductor device of claim 6, wherein:
the internal power supply circuit includes internal ground supply wiring and ground supply compensation capacitance coupled between the internal ground supply wiring and the well, the internal ground supply wiring providing a fluctuation in a ground supply potential on the internal ground supply wiring in response to fluctuations in the potential of the substrate.

8. The semiconductor device of claim 6, wherein:
the internal power supply circuit includes a first insulated gate field effect transistor (IGFET) coupled between an external power supply wiring and the internal power supply wiring.

9. The semiconductor device of claim 8, wherein:
the internal power supply circuit includes a second IGFET coupled between an external ground supply wiring and an internal ground supply wiring.

10. The semiconductor device of claim 9, wherein:
the first and second IGFETs have different conductivity types, the gate of the second IGFET being coupled to the external power supply wiring, the gate of the first IGFET being coupled to the external ground supply wiring.

11. A semiconductor device, comprising:
a semiconductor substrate;
a first well formed in the semiconductor substrate;
a memory portion formed in the first well, the memory portion including
a plurality of memory cells formed in the first well, and
at least one sense amplifier formed in the first well;
a voltage generator formed in the first well that provides a reference voltage to at least one of the memory cells; and
a second circuit unit formed in the substrate outside the first well.

12. The semiconductor device of claim 11, wherein:
the first well comprises an n-type semiconductor material.

13. The semiconductor device of claim 12, wherein:
the first well further includes a second well formed therein, the second well comprising p-type semiconductor material; and
the memory cells are dynamic random access memory (DRAM) cells that include n-channel insulated gate field effect transistors formed in the second well.

14. The semiconductor device of claim 11, wherein:
the second circuit unit includes at least a large-scale integrated logic circuit unit.

15. The semiconductor device of claim 11, wherein:
the memory portion is a DRAM macro that further includes an X-decoder, a Y-decoder, and a read/write buffer.

16. A semiconductor device, comprising:
a semiconductor substrate that includes a first well;
a memory cell array formed in the first well that includes a plurality of memory cells, the memory cells having data nodes that are capacitively coupled to the substrate;
an internal power supply circuit formed in the first well that generates a reference potential on a first supply line, the first supply line being capacitively coupled to the substrate; and
a circuit unit coupled to the substrate.

17. The semiconductor device of claim 16, wherein:
the memory cell array includes dynamic random access memory (DRAM) cells; and
the circuit unit includes a logic circuit unit.

18. The semiconductor device of claim 16, wherein:
the memory cell data nodes are capacitively coupled to the substrate by junction capacitance formed by differently doped semiconductor materials.

19. The semiconductor device of claim 16; wherein:
the first supply line is capacitively coupled to the substrate by parasitic capacitance formed by the supply line and dielectric material between the supply line and the substrate.

20. The semiconductor device of claim 16, wherein:
the circuit unit can generate noise in the substrate.
